(19) United States
(12) Patent Application Publication
(10) Pub. No.: US 2019/0074208 A1
(43) Pub. Date: Mar. 7, 2019

(54) WAFER SUPPORTING SYSTEM

(71) Applicant: FOXSEMICON INTEGRATED TECHNOLOGY, INC., Miao-Li Hsien (TW)

(72) Inventors: YI-CHUN CHIU, Miaoli Hsien (TW); CHUN-KAI HUANG, Miaoli Hsien (TW); CHIH-CHENG LU, Miaoli Hsien (TW); CHUN-CHUNG CHEN, Miaoli Hsien (TW); CHEN-TSU FU, Miaoli Hsien (TW); SHENG-FU TSAI, Miaoli Hsien (TW)

(21) Appl. No.: 16/004,524

(22) Filed: Jun. 11, 2018

(30) Foreign Application Priority Data
Sep. 6, 2017 (CN) 201710796170.9

(51) Int. Cl. H01L 21/683

(52) U.S. Cl. CPC H01L 21/6838

(57) ABSTRACT

A wafer supporting system includes a supporting pedestal. The supporting pedestal includes a main supporting body and a hollow frame surrounding the supporting pedestal. The main supporting body includes a top surface and a bottom surface opposite to the top surface, the top surface defined a plurality of vent grooves and a plurality of holding grooves. The main supporting body includes a plurality of holding channels extending through from the bottom surface to the holding grooves and a plurality of first through holes pass through from the top surface to the bottom surface, each holding groove is surrounded by a plurality of first through holes; an inner side surface of the hollow frame and a side wall of the supporting pedestal form a gap, and a plurality of exhaust cylinders are arranged in the annular gap and each exhaust cylinder is communicated with each vent groove.

### FIELD

This disclosure generally relates a wafer supporting system, configured to fix a wafer when being processed.

### BACKGROUND

In a semiconductor fabrication process, such as a chip fabrication process, a wafer carrier is frequently used to prevent fixed wafers from a vacuum adsorption means to prevent the wafer from moving or shifting. Also, wafers can experience various degrees of deformation during fabrication. For example, wafers may have a convex or concave surface towards a central area of the wafer due to inner stress. As such, uneven wafer surfaces can affect wafer exposure and development.

### BRIEF DESCRIPTION OF THE DRAWINGS

Implementations of the present technology will now be described, by way of example only, with reference to the attached figures.

FIG. 1 is top view of a wafer supporting system in accordance with one exemplary embodiment.

FIG. 2 is a cross-sectional view of the wafer supporting system of FIG. 1.

FIG. 3 is a working state of the device of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to illustrate details and features of the present disclosure better. The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like. The references “a plurality of” and “a number of” mean “at least two.”

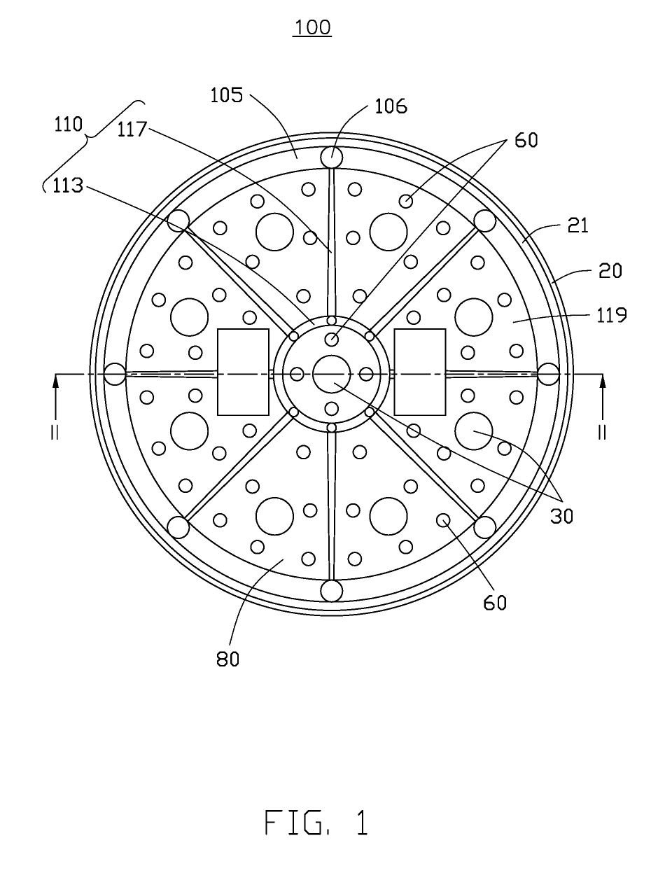

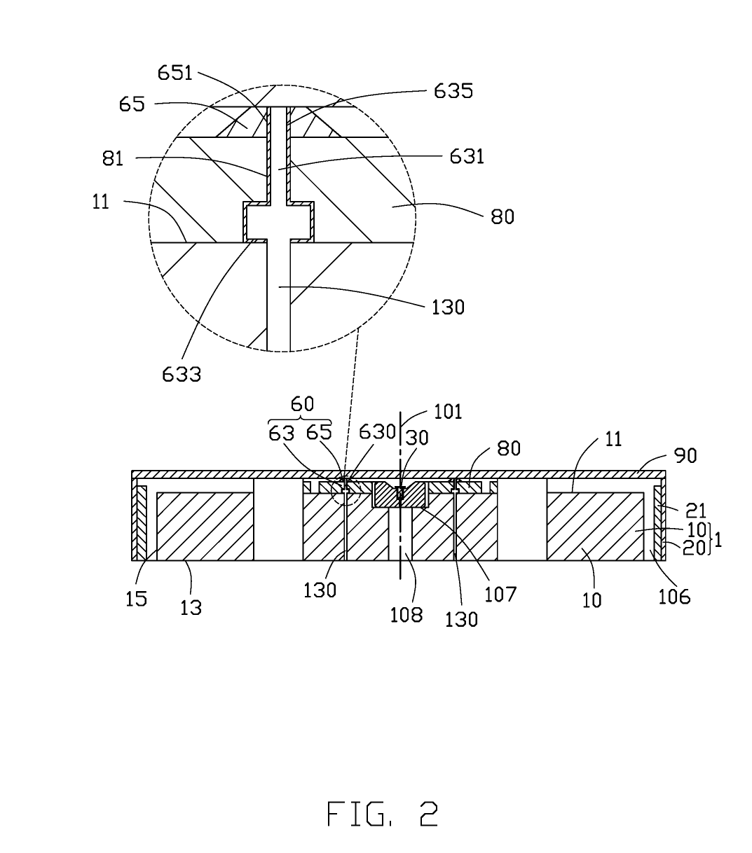

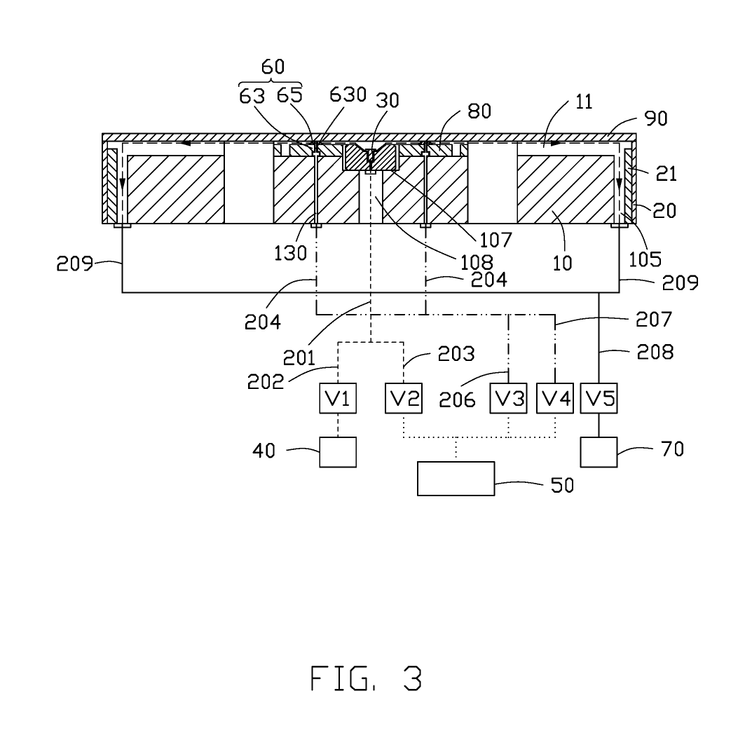

FIGS. 1-3 illustrate a wafer supporting system 100 according to one embodiment. The wafer supporting system 100 is configured to bear a wafer 90, as shown in FIG.2. The supporting system 100 includes a supporting pedestal 1 (shown in FIG.2), a plurality of non-contact type suckers 30 (shown in FIG.2), a pressure source 40 (shown in FIG.3), and a vacuum generator 50(shown in FIG.3), a plurality of adsorption supporting members 60(shown in FIG.2), a venting gas appliance 70 (shown in FIG.3) and a gasket 80(shown in FIG.3).

The supporting pedestal 1 is configured to bear a wafer 90 and includes a main supporting body 10 and a hollow frame 20 surrounding the main supporting body 10, as shown in FIG.2. The main supporting body 10 is substantially cylindrical. The main supporting body 10 includes a top surface 11, a bottom surface 13 opposite to the top surface 11 and a side wall 15 connecting the top surface 11 and the bottom surface 13.

The top surface 11 defines a vent groove 110, as shown in FIG.1. The vent groove 110 includes a first annular exhaust groove 113 surrounding a central axis of the main supporting body 10 and a plurality of strip exhaust slots 117 communicating with the first annular exhaust groove 113 in a radial form. In the illustrated embodiment, the number of the strip exhaust slots 117 is eight. The number of the strip exhaust slots 117 can be changed according to actual needs. The top surface 11 is divided into a plurality of bearing areas 119 by the vent groove 110, and each bearing area 119 is substantially sector.

The top surface 11 of the main supporting body 10 further defines a plurality of holding grooves 107, as shown in FIG.2. FIG. 2 is a cross-sectional view of the wafer supporting system of FIG. 1., so FIG. 2 only illustrates one holding groove 107, in fact, below of each non-contact type sucker 30 is the holding groove 107. Each holding groove 107 is configured to receive a non-contact type sucker 30. In the illustrated embodiment, each bearing area 119 includes one holding groove 107, and the holding grooves 107 are distributed in a same circle. The width of the holding groove 107 is little larger than a diameter of the non-contact type sucker 30.

The main supporting body 10 further includes a plurality of holding channels 108, as shown in FIG.2. FIG. 2 is a cross-sectional view of the wafer supporting system of FIG. 1., so FIG. 2 only shows one holding channels 108. In fact, Each holding channel 108 is located below the holding groove 107 and communicated with the corresponding holding groove 107. That is, the holding channel 108 extends from the bottom of the holding groove 107 to the bottom surface 13 of the main supporting body 10, and the holding groove 107 is coaxially arranged with a corresponding holding channel 108. The holding channel 108 is configured to receive a first main pipe 201, such as shown in FIG.2. The main pipe 201 is configured to connect the non-contact type suckers 30 and the pressure source 40.

The main supporting body 10 further includes a plurality of first through holes 130 extending through from the top surface 11 to the bottom surface 13, as shown in FIG.2. Each holding groove 107 is surrounded by a plurality of first through holes 130. In the illustrated embodiment, each holding channel 108 is surrounded by six first through holes 130, as shown in FIG.1.

The hollow frame 20 surrounds the main supporting body 10 and an annular gap 105 is formed between an inner side surface 15 of the hollow frame 20 and the side wall 15 of the main supporting body 10, as shown in FIG.2. The hollow frame 20 is higher than the main supporting body 10, and a top end of the hollow frame 20 is higher than a top surface 11 of the main supporting body 10. A plurality of exhaust cylinders 106 are arranged in the annular gap 105 and communicated with the strip exhaust slots 117. In this embodiment, the exhaust cylinders 106 are evenly distributed in the annular gap 105, and the diameter of each exhaust cylinder 106 is substantially the same as the width of the annular gap 105. Air flow along the strip exhaust slots 117 can be discharged through the exhaust cylinder 106.

A non-contact type suckers 30 received in each holding groove 107. The non-contact type sucker 30 can be any type known in the art. In this embodiment, the non-contact type suckers 30 may be Bernoulli suckers. The non-contact type suckers 30 may each arranged in a corresponding holding groove 107 and protrude from the top surface 11. Non-contact type suckers 30 are connected with the pressure device 40 such as pipes, and the pressure source 40 are configured to provide compressed air for sucker 30 usage. Arrow directions in FIG.3 represents a variety of different air flow directions of air flow from the non-contact type suckers 30.

The pressure source 40 provides pressurized air for the non-contact type suckers 30.

As shown in FIG.1, the adsorption supporting members 60 are uniformly distributed on the top surface 11 and also configured to adsorb and support the wafer 90. The adsorption supporting members 60 are set around each non-contact type sucker 30 and communicated with the first through holes 130. The top end of each adsorption supporting member 60 protrudes from the top surface of each non-contact type sucker 30, and the non-contact type sucker 30 and the adsorption supporting member 60 are used to adsorb the wafer 90 at different stages.

In this embodiment, the adsorption supporting members 60 includes a cylindrical hollow member 63 and a supporting plate 65. A cross section of the cylindrical hollow member 63 is substantially a T-shaped and includes a vent hole 631 along its central axis. The cylindrical hollow member 63 includes a first end 633 and a second end 635 opposite to the first end 633. A size of the first end 633 is larger than a size of the second end 632. The first end 633 is fixed on the top surface 11, and each vent hole 631 is in communication with the first through holes 130. The first through hole 130 and each vent hole 631 can share a common axis, and the common axis passes through the first through hole 130 and each vent hole 631.

A cross section of the supporting plate 65 is substantially trapezoidal and includes a second through hole 651. The supporting plate 65 is disposed on the gasket 80 and the second end 635 of the cylindrical hollow member 63 passes through the second through hole 651, and the second end 635 is level with the top surface of the supporting plate 65. The supporting plate 65 is made of plastic or foam, to avoid scratching the wafer 90.

A gasket 80 is fixed on the top surface 11. The gasket 80 may be made from soft materials, such as plastics or resins. A size of each gasket 80 is substantially equal in size to the area of the top surface 11. The gasket 80 includes a plurality of mounting holes 81, and the cylindrical hollow member 63 penetrates the mounting holes 81. The gasket 80 exposes the vent grooves 110. The gasket 80 also includes a plurality of through holes to expose the non-contact type sucker 30.

As shown in FIG.3, the wafer supporting system 100 further includes a first valve V1, a second valve V2, a third valve V3, a fourth valve V4, and a fifth valve V5. The wafer supporting system 100 further comprises a first main pipe 201, a first branch pipe 202, a plurality of third branch pipes 203, a plurality of third branch pipes 204, a second main pipe 205, a fourth branch pipe 206, a fifth branch pipe 207, a third main pipe 208 and a plurality of third branch pipes 209.

One end of the first main pipe 201 is connected with the non-contact type suckers 30, the other end of the main pipe 201 forks and forms a first branch pipe 202 and a second branch pipe 203. The end of the first branch pipe 202 away from the main pipe 201 is connected to the pressure source 40 and the first valve V1 is mounted between the pressure source 40 and the first branch pipe 202, to control opening and closing of the first branch pipe 202. The pressure source 40 is configured to provide pressured air for each non-contact type suckers 30 via a main pipe 201 and branch pipe 202.

The second valve V2 is mounted between the second branch pipe 203 and the vacuum generator 50. A weak vacuum is provided by the vacuum generator 50 for each non-contact type suckers 30 via the main pipe 201 and the second branch pipe 203.

One end of each third branch pipe 204 is connected with the first through holes 130. The other end of the third branch pipes 204 are converge together to the second main pipes 205. The second main pipes 205 forks and forms the fourth branch pipe 206 and the fifth branch pipe 207. The third valve V3 is installed between the vacuum generator 50 and the fourth branch pipe 206. A weak vacuum is provided by the vacuum generator 50 for the adsorption supporting members 60 via the third branch pipe 204, the second main pipes 205 and the fourth branch pipe 206.

The fourth valve V4 is installed between the vacuum generator 50 and the first through holes 130. The fourth valve V4 opens and shuts the plurality of first through holes 130 via third branch pipes 204 and branch pipe 206 and provides a strong vacuum for the adsorption supporting members 60.

One end of each sixth branch pipe 209 is connected with the exhaust cylinder 106. The other end of each the sixth branch pipes 209 are converged together to connect the third main pipe 208. The fifth valve V5 is installed between the venting gas appliance 70 and the third main pipe 208. The fifth valve V5 opens and shuts the exhaust cylinder 106 via the sixth branch pipe 209 and the third main pipe 208 and exhausts air from the non-contact type suckers 30.

When the first valve V1 opens, the pressure source 40 is able to provide pressure air for the non-contact type suckers 30 via a first main pipe 201 and a first branch pipe 202. When the second valve V2 opens, the vacuum generator 50 is able to provide weak vacuum for the non-contact type suckers 30 via the first main pipe 201 and the second branch pipe 203. When the third valve V3 opens, the vacuum generator 50 is able to provide weak vacuum for the adsorption supporting members 60 via the third branch pipes, the second main pipe 205 and a fourth branch pipe 206. When the fourth valve V4 opens, the vacuum generator 50 is able to provide strong vacuum for the adsorption supporting members 60 via the third branch pipes 204, the second main pipe 205 and a fifth branch pipe 207. When the fifth valve V5 opens, the venting gas appliance 70 is able to discharge air flow from the exhaust cylinder 106 via the sixth branch pipe 209 and the third main pipes 204.

When the wafer supporting system 100 is applied to adsorb and support a wafer 90, includes three stages as follows.

The first stage: the opening of the first valve V1 and the fifth valve V5; and the closing of the second valve V2, the third valve V3, and the fourth valve V4. The wafer 90 is provided above the wafer supporting system 100 using a gripping device(not shown), and the pressure source 40 is connected with the first valve V1. Air flow from the pressure source 40 rapidly flows into the non-contact type suckers 30 via the main pipe 201 set in the holding channel 108, and the non-contact type sucker 30 can rapidly adsorb the wafer 90 without contacting the wafer 90. Air flow continues to be input to the non-contact type suckers 30, and the air flow from the non-contact type suckers 30 continues to flow along the vent grooves 110 and the exhaust cylinders 106, and then discharged from the fifth valve V5, as shown in FIG.3, and the arrow represents a direction of the air flow.

The second stage: further opening of the fourth valve V4. When the non-contact type sucker 30 adsorbs until the wafer 90 contacts the supporting plate 65, the wafer 90 also covers the hollow frame 20. The wafer 90 and the hollow frame 20 together form an airtight space, and top surface of the adsorption supporting member 60 is level with the hollow frame 20. When the vacuum value reaches a set value, the first valve V1 and fifth valve V5 are closed.

The third stage: the opening of the second valve V2 and the third valve V3, and the closing of the fourth valve V4. A weak vacuum is maintained for the closed space formed by using the wafer 90 and the hollow frame 20, the adsorption supporting members 60 can thus maintain a stable adsorption of the wafer 90.

The embodiments shown and described above are only examples. Therefore, many commonly-known features and details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. A wafer supporting system comprising:
a supporting pedestal, comprising a main supporting body and a hollow frame surrounding the supporting pedestal;
the main supporting body comprising a top surface and a bottom surface opposite to the top surface, the top surface defined a plurality of vent grooves and a plurality of holding grooves, the main supporting body comprising a plurality of holding channels extending through from the bottom surface to the holding grooves and a plurality of first through holes pass through from the top surface to the bottom surface, each holding groove is surrounded by a plurality of first through holes; an inner side surface of the hollow frame and a side wall of the supporting pedestal form a gap, and a plurality of exhaust cylinders are arranged in the annular gap and each exhaust cylinder is communicated with each vent groove;
a plurality of non-contact type suckers, each non-contact type sucker is mounted in each holding groove;
a plurality of adsorption supporting members, the adsorption supporting members are mounted on the top surface;
a pressure source connected with the plurality of non-contact type suckers via the holding channel and configured to provide compressed air for the non-contact type suckers; and
a vacuum generator connected with the adsorption supporting members via the first through holes and configured to provide vacuum for the adsorption supporting members.

2. The wafer supporting system of claim 1, wherein the main supporting body is substantially a cylinder, and the hollow frame is higher than the main supporting body.

3. The wafer supporting system of claim 1, wherein the wafer supporting system further comprises a gasket fixing on the top surface, a size of the gasket is equal to an area of the top surface and the gasket exposes the vent grooves.

4. The wafer supporting system of claim 1, wherein the vent grooves comprises a first annular exhaust groove surrounding a central axis of the main supporting body and a plurality of strip exhaust slots communicated with the first annular exhaust groove in a radial form.

5. The wafer supporting system of claim 4, wherein the top surface defines a plurality of bearing areas by the plurality of vent grooves, each bearing area arranges with one holding grooves.

6. The wafer supporting system of claim 3, wherein the adsorption supporting members is uniformly distributed about its top surface, each adsorption supporting member communicates with each first through hole, each top end of the adsorption supporting member protrudes towards a top surface of each non-contact type sucker, and each top end of the adsorption supporting is level with the top end of the hollow frame.

7. The wafer supporting system of claim 6, wherein the adsorption supporting members comprises a cylindrical hollow member mounted on the top surface and a supporting plate penetrate the cylindrical hollow member, the cylindrical hollow member is located on the gasket, a cross section of the cylindrical hollow member is substantially T-shaped, and a cross section of the supporting plate is substantially trapezoid.

8. The wafer supporting system of claim 7, wherein the cylindrical hollow member penetrates the mounting hole and comprises a first end and a second end opposite to the first end, a size of the first end is larger than a size of the second end, the first end is fixed on the top surface, the cylindrical hollow member defines a vent hole along its central axis and each vent hole is communicated with the first through holes.

9. The wafer supporting system of claim 3, wherein the gasket is made from soft materials.

10. The wafer supporting system of claim 1, wherein the wafer supporting system further comprises a main pipe disposing in the holding channel and a first valve, one end of the main pipe is connected with the one non-contact type sucker, the other end of the main pipe forks and forms a first branch pipe and a second pipe, one end of the first branch pipe away from the main pipe is connected with the pressure source, and the first valve is mounted between the pressure source and the first branch pipe and configured to control the first branch pipe opening and closing.

11. The wafer supporting system of claim 10, wherein the wafer supporting system further comprises a second valve, the second valve is mounted between the second branch pipe and the vacuum generator device.

12. The wafer supporting system of claim 11, wherein the wafer supporting system further comprises a plurality of third branch pipes, a second main pipe, a fourth branch pipe, a fifth branch pipe, a third valve and a fourth valve; one end of each third branch pipe is connected with the first through holes, the other end of each third branch pipes are converge together to the second main pipes, the second main pipes forks and forms a fourth branch pipe and the fifth branch pipe, the third valve is installed the vacuum generator and the fourth branch pipe, the fourth valve is installed between the vacuum generator and the fifth branch pipe.

13. The wafer supporting system of claim 12, wherein the wafer supporting system further comprises a plurality of sixth branch pipes, a third main pipe and a fifth valve, one end of each sixth branch pipe is connected with the exhaust cylinder, the plurality of the sixth branch pipe are converged together to connect the third main pipe, the fifth valve is installed between the venting gas appliance and the third main pipe.

14. The wafer supporting system of claim 13, wherein the non-contact type sucker is a Bernoulli sucker.
